(19) United States
(12) Patent Application Publication
(10) Pub. No.: US 2015/0014826 A1
(43) Pub. Date: Jan. 15, 2015

(54) SEMICONDUCTOR DEVICE

(71) Applicant: KABUSHIKI KAISHA TOSHIBA, Tokyo (JP)

(72) Inventors: Hideyuki URA, Himeji (JP); Hiroaki YAMASHITA, Himeji (JP); Syotaro ONO, Tatsuno (JP); Masaru IZUMISAWA, Himeji (JP)

(73) Assignee: KABUSHIKI KAISHA TOSHIBA, Tokyo (JP)

(21) Appl. No.: 14/188,403

(22) Filed: Feb. 24, 2014

(30) Foreign Application Priority Data
Jul. 11, 2013 (JP) 2013-145372

(51) Int. Cl. H01L 29/06

(52) U.S. Cl. CPC H01L 29/0688
USPC 257/655

(57) ABSTRACT

According to one embodiment, a semiconductor device includes a second electrode opposite to a first electrode, a first semiconductor layer provided above the first electrode, the first semiconductor layer having first semiconductor regions of a first conductivity type alternating with second semiconductor regions of a second conductivity type in a direction generally parallel to the first electrode A second semiconductor layer of the second conductivity type is provided on the first semiconductor layer Third extend into the first semiconductor layer from the second semiconductor layer. At least one first semiconductor region includes a first portion containing hydrogen ions and a second portion between the first portion and the second semiconductor layer that has a dopant concentration lower than that of the first portion.

### CROSS-REFERENCE TO RELATED APPLICATION

This application is based upon and claims the benefit of priority from Japanese Patent Application No. 2013-145372, filed Jul. 11, 2013, the entire contents of which are incorporated herein by reference.

### FIELD

Embodiments described herein relate to semiconductor devices.

### BACKGROUND

Semiconductor devices (e.g., power semiconductor devices) with high-speed switching characteristics and reverse breakdown voltages (withstand voltages) in the range of tens to hundreds of volts are used for power conversion, control, and so on in home electric appliances, communication equipment, in-vehicle motors, etc. Among these semiconductor devices, a semiconductor device with a super-junction structure having both a high breakdown voltage and a low on-resistance is becoming popular.

In a semiconductor device with a super-junction structure, the on-resistance becomes lower as the dopant concentration in n-type pillar regions constituting drift layers is set higher. However, the dopant concentration in n-type pillar regions is determined by specifications of the semiconductor wafer used in a wafer process or process conditions for forming the super-junction structure. Moreover, after a super-junction structure is formed, the on-resistance cannot be changed.

### DESCRIPTION OF THE DRAWINGS

FIG. 1 is a schematic cross-sectional view depicting a semiconductor device according to a first embodiment.

FIG. 2 is a schematic plan view depicting the semiconductor device according to the first embodiment.

FIG. 3 is a schematic cross-sectional view depicting a semiconductor device according to a second embodiment.

FIG. 4 is a schematic cross-sectional view depicting a semiconductor device according to a third embodiment.

### DETAILED DESCRIPTION

In general, according to one embodiment, a semiconductor device includes a first electrode on a substrate, a second electrode separated from the first electrode in a first direction, and a first semiconductor layer provided above the first electrode. The first semiconductor layer includes first semiconductor regions of a first conductivity type (e.g., n-type) that alternate with second semiconductor regions of a second conductivity type (e.g., p-type) in a second direction substantially perpendicular with the first direction. A second semiconductor layer of the second conductivity type is provided on the first semiconductor layer. A third semiconductor layer of the first conductivity type is provided on the second semiconductor layer and in contact with the second electrode. Third electrodes extend from the third semiconductor layer into the first semiconductor regions. An insulating film is provided between each of the third electrodes and the third semiconductor layer, the second semiconductor layer, and the first semiconductor regions. At least one of the first semiconductor regions comprises a first portion containing hydrogen ions and a second portion between the first portion and the second semiconductor layer, the second portion having a dopant concentration lower than that of the first portion.

Hereinafter, with reference to the drawings, example embodiments will be described. In the following description, like elements are denoted by common reference numerals. Description of an element once explained may be omitted.

### First Embodiment

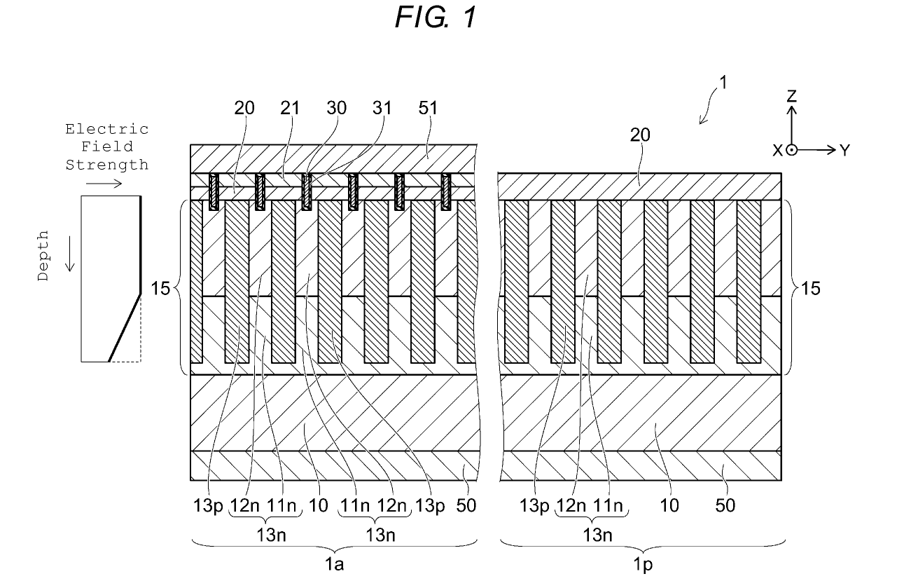

FIG. 1 is a schematic cross-sectional view depicting a semiconductor device according to a first embodiment.

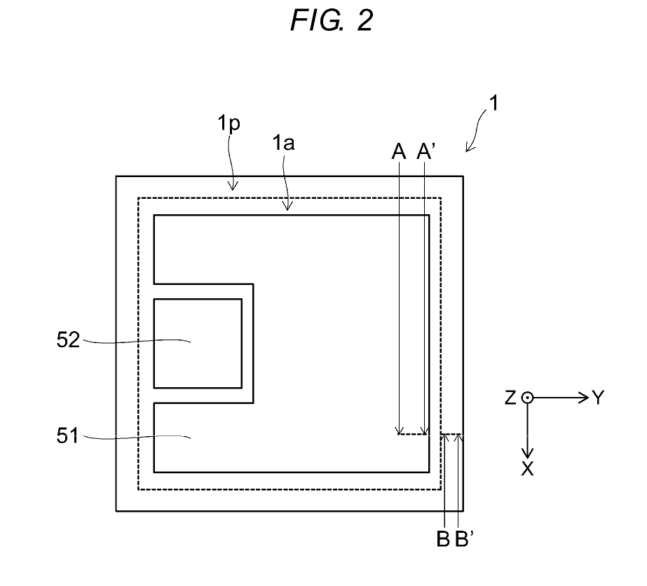

FIG. 2 is a schematic plan view depicting the semiconductor device according to the first embodiment.

FIG. 1 shows a cross-section along line A-A′ in an active region 1a (first region) of a semiconductor device 1 shown in FIG. 2, and a cross-section along line B-B′ in a peripheral region 1p (second region) of the semiconductor device 1. FIG. 1 also shows on the left the relationship between a depth and an electric field strength in the active region 1a and the peripheral region 1p when the semiconductor device 1 is off. The depth of the semiconductor device 1 means a depth in the vicinity of a junction between an n-type semiconductor region 13n and a p-type semiconductor region 13p to be described below.

In this embodiment, a direction from a drain electrode 50 toward a semiconductor layer 15 (or a source electrode 51) is a Z direction (first direction), a direction intersecting with the Z direction is a Y direction (second direction), and a direction intersecting with the Z direction and the Y direction is an X direction.

The semiconductor device 1 according to the first embodiment is a power semiconductor device with an upper-lower electrode structure. The semiconductor device 1 is provided with the active region 1a and the peripheral region 1p. The peripheral region 1p surrounds the active region 1a. In the active region 1a, a plurality of metal-oxide-semiconductor field-effect transistors (MOSFETs) are disposed. The drain electrode 50 is opposite to the source electrode 51 across a semiconductor. In the semiconductor device 1, the voltage of gate electrodes is controlled, thereby turning on (on state) or turning off (off state) current conductance between the drain electrode 50 and the source electrode 51. In the on state, an electric current flows through the active region 1a between the source and drain.

In the semiconductor device 1, an n⁺-type drain layer 10 is provided on the drain electrode 50 (first electrode). The semiconductor layer 15 (first semiconductor layer) is provided above the drain electrode 50. The drain layer 10 is provided between the drain electrode 50 and the semiconductor layer 15.

The semiconductor layer 15 has a super-junction structure in which n-type semiconductor regions 13n (first semiconductor regions) and p-type semiconductor regions 13p (second semiconductor regions) are arranged alternately in the Y direction, for example. The semiconductor regions 13n constitute drift layers of the MOSFETs. In the Y direction, the width of the semiconductor regions 13p and the width of the semiconductor regions 13n sandwiched between the semiconductor regions 13p are the same. The semiconductor regions 13p extends in the X direction.

A p-type base layer 20 (second semiconductor layer) is provided on the semiconductor layer 15. The base layer 20 abuts the semiconductor regions 13p of the super-junction structure.

In the active region 1a, an n⁺-type source layer 21 (third semiconductor layer) is also provided on the base layer 20. The source electrode 51 (second electrode) is provided on the source layer 21. In the active region 1a, the source layer 21 is connected to the source electrode 51. In the peripheral region 1p, the source electrode 51 is not provided. In the active region 1a, gate electrodes 30 (third electrodes) abut each semiconductor region 13n, the base layer 20, and the source layer 21 via a gate insulating film 31. The gate electrodes 30 extend in the X direction. The gate electrodes 30 are electrically connected to a gate pad 52.

In the active region 1a and the peripheral region 1p, each of the semiconductor regions 13n includes a first portion 11n located on the drain electrode 50 side, and a second portion 12n sandwiched between the first portion 11n and the base layer 20.

In this specific embodiment, the n⁺-type and n-type are called a “first conductivity type” and the p-type is called a “second conductivity type.” In addition, the n⁺-type has a higher dopant concentration than the n-type. Examples of dopant elements used in n⁺-type and n-type regions, layers, and materials include phosphorus (P), arsenic (As), and antimony (Sb). Examples of p-type dopant elements include boron (B).

For example, in the active region 1a and the peripheral region 1p, phosphorus (P) is implanted into the semiconductor regions 13n having the super-junction structure. Boron (B) is implanted into the semiconductor regions 13p. Furthermore, hydrogen ions (protons (H+)) are implanted into the first portions 11n, and heat treatment is conducted. Hydrogen is implanted from the side of the drain layer 10 after the formation of the super-junction structure. Hydrogen is not implanted into the second portions 12n.

The hydrogen implantation into the first portions 11n results in the dopant concentration in the first portions 11n being higher than the dopant concentration in the second portions 12n. In the concentration profile of hydrogen ions in the first portions 11n, the concentration of hydrogen is higher toward the drain electrode 50. The dopant concentration in the second portions 12n is equal to the dopant concentration in the semiconductor regions 13p.

Here, the “dopant concentration” means an effective concentration of dopant elements contributing to the conductivity of the semiconductor material. For example, when a semiconductor material has both electron donor dopants and electron acceptor dopants, the dopant concentration is obtained by subtracting the amount of donors and acceptors for each other to provide the concentration of the activated dopant elements.

The electric field strength at junctions between the second portions 12n and the semiconductor regions 13p shows a constant value in the Z direction (depth direction). The electric field strength at junctions between the first portions 11n and the semiconductor regions 13p forms a gradient in the Z direction.

The material of the drain layer 10, the semiconductor regions 13n and 13p, the base layer 20, and the source layer 21 includes silicon (Si) or other semiconducting materials, for example. The above-described dopant elements are introduced into the drain layer 10, the semiconductor regions 13n and 13p, the base layer 20, and the source layer 21. The drain layer 10, the semiconductor regions 13n and 13p, the base layer 20, and the source layer 21 are also subjected to annealing to activate the dopant elements.

The material of the source electrode 51 and the drain electrode 50 includes at least one of such metals as aluminum (Al), nickel (Ni), copper (Cu), titanium (Ti), and tungsten (W).

The material of the gate electrodes 30 includes a semiconductor into which a dopant element is introduced (e.g., a boron-doped polysilicon), or a metal (e.g., tungsten). The gate insulating films 31 include silicon dioxide (SiOx), silicon nitride (SiNx), or the like.

The semiconductor device 1 can be formed by forming a plurality of semiconductor devices 1 on a silicon wafer by a wafer process and then dividing the plurality of semiconductor devices 1 into pieces. The silicon wafer is what is called a commercial product. The dopant concentration of the silicon wafer is a concentration predetermined by, for example, customer specifications or design specifications.

During the formation of the super-junction structure in the wafer process, the concentration of dopants included in the super-junction structure can be changed or set to various desired values. However, in order to associate dopant concentration and process conditions with device performance experiments, simulations, and the like are required in advance. Moreover, if the semiconductor device is changed in design, the association between dopant concentration and process conditions may have to be re-determined from the start. Here, change in design means a change in dimensions of a semiconductor device, for example. Furthermore, after actual fabrication of the super-junction structure, the dopant concentration cannot be changed.

By contrast, in the first embodiment, independently of the specifications of the silicon wafer and the process conditions for forming the super-junction structure, hydrogen is introduced into the semiconductor regions 13n, and heat treatment (temperature: 300° C. to 500° C. (the same applies hereinafter)) is conducted, thus the concentration in the first portions 11n can be easily changed. That is, the on-resistance can be controlled irrespective of the initial specifications of the silicon wafer and the process conditions used to fabricate the super-junction structure. For example, by setting the concentration of hydrogen included in the first portions 11n to be high, a semiconductor device with a low on-resistance is realized. Moreover, even after the formation of the super-junction structure, the concentration in the first portions 11n can still be changed.

Furthermore, in the first embodiment, by including hydrogen in the first portions 11n, the lifetime of carriers in the drift layers can be controlled. For example, when parasitic diodes are in an on state, holes injected from the parasitic diodes may accumulate in the drift layers. Here, the parasitic diodes are, for example, pn diodes formed by the base layer 20 and the second portions 12n.

When the parasitic diodes are in an off state (at the time of reverse recovery, recovery), the holes h are discharged through the base layer 20 into the source electrode 51, for example. The hole current at that time is called a recovery current. Here, if the drift layers do not have a sufficient resistance to the hole current, the semiconductor device 1 may be damaged.

In the semiconductor device 1, as a way to cause holes to quickly disappear, the first potions 11n contain hydrogen. Owing to this, the lifetime of the holes in the first portions 11n shortens, and thus injection of holes into built-in (parasitic) diodes is reduced. As a result, the semiconductor device 1 having a high recovery current resistance is realized.

### Second Embodiment

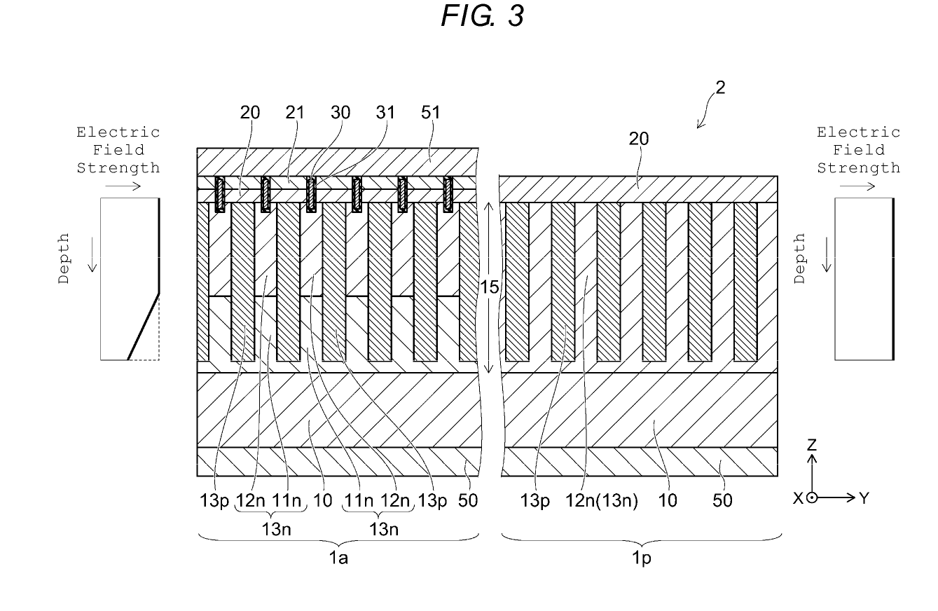

FIG. 3 is a schematic cross-sectional view depicting a semiconductor device according to a second embodiment.

FIG. 3 shows on the left the relationship between a depth and an electric field strength in an active region 1a when a semiconductor device 2 is in the off state. FIG. 3 shows on the right the relationship between a depth and an electric field strength in a peripheral region 1p when the semiconductor device 2 is in the off state.

In the semiconductor device 2, hydrogen is selectively implanted into the active region 1a, and heat treatment is conducted. That is, in the semiconductor device 2, each of the semiconductor regions 13n includes a first portion 11n and a second portion 12n in the active region 1a. In the peripheral region 1p, each of the semiconductor regions 13n does not include a first portion 11n. In the peripheral region 1p, each of the semiconductor regions 13n is formed by a second portion 12n.

In the peripheral region 1p, the dopant concentration in the semiconductor regions 13n and the dopant concentration in the semiconductor regions 13p are balanced in the Z direction. Therefore, in the peripheral region 1p, the electric field strength at junctions between the semiconductor regions 13n and the semiconductor regions 13p has a constant value in a depth direction. In other words, when the semiconductor device 2 is in the off state, the length of depletion layers extending in the semiconductor regions 13n and the length of depletion layers extending in the semiconductor regions 13p are the same. Consequently, in the semiconductor device 2 in the off state, the breakdown voltage in the peripheral region 1p increases further than that in the semiconductor device 1.

### Third Embodiment

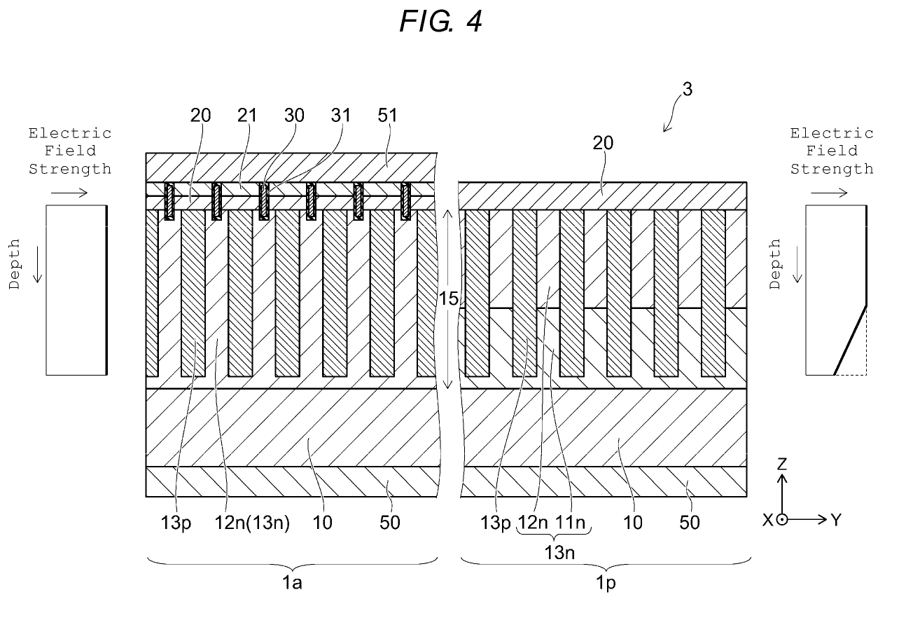

FIG. 4 is a schematic cross-sectional view showing a semiconductor device according to a third embodiment.

FIG. 4 shows on the left the relationship between a depth and an electric field strength in an active region 1a when a semiconductor device 3 is in the off state. FIG. 4 shows on the right the relationship between a depth and an electric field strength in a peripheral region 1p when the semiconductor device 3 is off.

In the semiconductor device 3, hydrogen is selectively implanted into the peripheral region 1p, and heat treatment is conducted. That is, in the semiconductor device 3, each of the semiconductor regions 13n includes a first portion 11n and a second portion 12n in the peripheral region 1p. In the active region 1a, each of the semiconductor regions 13n does not include a first portion 11n. In the active region 1a, each of the semiconductor regions 13n is formed by a second portion 12n.

Hole current as described above tends to accumulate in the peripheral region 1p. This is because a source electrode 51 into which hole current can be discharged is not provided in the peripheral region 1p. Accordingly, in the semiconductor device 3, as a way to cause holes to quickly disappear in the peripheral region 1p, the peripheral region 1p contains hydrogen. Owing to this, the lifetime of holes in the first portions 11n in the peripheral region 1p is shortened. As a result, the semiconductor device 3 having a high recovery current resistance in the peripheral region 1p is realized.

### Fourth Embodiment

Hydrogen implanted from the drain side is implanted into the semiconductor regions 13p as well as the semiconductor regions 13n. Thereafter, heat treatment is conducted. Therefore, after the implantation of hydrogen, p-type dopants contained in the semiconductor regions 13p may be negated by the hydrogen, resulting in a reduction in the dopant concentration in the semiconductor regions 13p.

In this case, the dopant concentration in the semiconductor regions 13p can be controlled in advance so that in the dopant concentration profile of the semiconductor regions 13p, the concentration becomes higher toward the drain side.

Additionally, in the embodiments, “on” in the expression “a region A is provided on a region B” may be used to mean that the region A does not contact the region B and the region A is provided above the region B, as well as being used to mean that the region A contacts the region B and the region A is provided directly on the region B. Further, the expression “a region A is provided on a region B” may also be applied to the case where the region A and the region B are inverted in orientation to locate the region A below the region B, and the case where the region A and the region B are arranged side by side. This is because even when the semiconductor devices according to the embodiments are rotated, the structures of the semiconductor devices before and after the rotation remain unchanged.

The embodiments have been described above with reference to specific examples. However, the embodiments are not limited to these specific examples. That is, these examples maybe changed in various particulars of design as appropriate by those skilled in the art and still fall within the scope of the embodiments disclosed herein. The elements that the examples include, and their arrangements, materials, conditions, shapes, sizes, and so on are not limited to those illustrated and can be changed as appropriate.

Moreover, the elements that the various specific embodiments include can be combined as far as technically possible. The combinations of specific examples fall within the scope of the disclosure as long as they include the features of the embodiments. Those skilled in the art can arrive at various modifications and alterations of the disclosed embodiments. These modifications and alterations are understood to fall within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode on a substrate;
a second electrode separated from the first electrode in a first direction;
a first semiconductor layer provided above the first electrode and including first semiconductor regions of a first conductivity type that alternate with second semiconductor regions of a second conductivity type in a second direction substantially perpendicular with the first direction;
a second semiconductor layer of the second conductivity type provided on the first semiconductor layer;
a third semiconductor layer of the first conductivity type provided on the second semiconductor layer and in contact with the second electrode;
third electrodes extending from the third semiconductor layer into the first semiconductor regions; and
an insulating film provided between each third electrode and each of the third semiconductor layer, the second semiconductor layer, and the first semiconductor regions;
wherein at least one first semiconductor region comprises a first portion containing hydrogen ions and a second portion that is between the first portion and the second semiconductor layer and has a dopant concentration lower than that of the first portion.

2. The semiconductor device of claim 1, wherein the substrate includes a first substrate region and a second substrate region, and the second electrode is in the first substrate region and not in the second substrate region.

3. The semiconductor device of claim 2, wherein the third electrodes are in the first substrate region and not in the second substrate region.

4. The semiconductor device of claim 3, wherein the third semiconductor layer is in the first substrate region and not in the second substrate region.

5. The semiconductor device of claim 2, wherein the second substrate region surrounds the first substrate region.

6. The semiconductor device of claim 2, wherein the first portion of the at least one first semiconductor region is in the first region.

7. The semiconductor device of claim 2, wherein each first semiconductor region in the first substrate region comprises a respective first portion containing hydrogen ions and a respective second portion that is between the respective first portion and the second semiconductor layer, the respective second portion having a dopant concentration lower than that of the respective first portion.

8. The semiconductor device of claim 2, wherein each first semiconductor region comprises a respective first portion containing hydrogen ions, and a respective second portion between the respective first portion and the second semiconductor layer, the respective second portion having a dopant concentration lower than that of the respective first portion.

9. The semiconductor device of claim 2, wherein first semiconductor regions in the first substrate region comprise a respective first portion containing hydrogen ions, and a respective second portion between the respective first portion and the second semiconductor layer, the respective second portion having a dopant concentration lower than that of the respective first portion, and first semiconductor regions in the second substrate region do not have a portion containing hydrogen ions.

10. The semiconductor device of claim 2, wherein the at least one first semiconductor is in the second substrate region.

11. The semiconductor device of claim 2, wherein first semiconductor regions in the second substrate region each comprise a respective first portion containing hydrogen ions, and a respective second portion between the respective first portion and the second semiconductor layer, the respective second portion having a dopant concentration lower than that of the respective first portion, and first semiconductor regions in the first substrate region do not have a portion containing hydrogen ions.

12. The semiconductor device of claim 1, wherein each first semiconductor region semiconductor region comprises a respective first portion containing hydrogen ions, and a second portion between the respective first portion and the second semiconductor layer and having a dopant concentration lower than that of the respective first portion.

13. The semiconductor device of claim 1, wherein the first conductivity type is n-type and the second conductivity type is p-type.

14. A semiconductor device, comprising
a first electrode on a substrate, the substrate having a first substrate region and a second substrate region, the second substrate region surrounding the first substrate region;
a second electrode separated from the first electrode in a first direction;
a first semiconductor layer provided above the first electrode and including first semiconductor regions of a first conductivity type that alternate with second semiconductor regions of a second conductivity type in a second direction substantially perpendicular with the first direction;
a second semiconductor layer of the second conductivity type provided on the first semiconductor layer;
a third semiconductor layer of the first conductivity type provided on the second semiconductor layer and in contact with the second electrode;
third electrodes extending from the third semiconductor layer into the first semiconductor regions; and
an insulating film provided between each third electrode and each of the third semiconductor layer, the second semiconductor layer, and the first semiconductor regions;
wherein at least one first semiconductor region comprises a first portion containing hydrogen ions and a second portion that is between the first portion and the second semiconductor layer and has a dopant concentration lower than that of the first portion,
the second electrode is in the first substrate region and not in the second substrate region,
the third electrodes are in the first substrate region and not in the second substrate region, and
the third semiconductor layer is in the first substrate region and not in the second substrate region.

15. The semiconductor device of claim 14, wherein the at least one first semiconductor region is in the first substrate region.

16. The semiconductor device of claim 14, wherein the at least one first semiconductor region is in the second substrate region.

17. The semiconductor device of claim 14, wherein each first semiconductor region comprises a respective first portion containing hydrogen ions, and a respective second portion between the respective first portion and the second semiconductor layer, the respective second portion having a dopant concentration lower than that of the respective first portion.
